(19) United States
(12) Patent Application Publication
(10) Pub. No.: US 2015/0187410 A1
(43) Pub. Date: Jul. 2, 2015

(54) TESTING A WIDE FUNCTIONAL INTERFACE OF A DEVICE INTEGRATED ON AN SIP WITHOUT DEDICATED TEST PINS

(71) Applicants: Christopher J Nelson, Gilbert, AZ (US); David J Zimmerman, El Dorado Hills, CA (US)

(72) Inventors: Christopher J Nelson, Gilbert, AZ (US); David J Zimmerman, El Dorado Hills, CA (US)

(21) Appl. No.: 14/142,809

(22) Filed: Dec. 28, 2013

(51) Int. Cl. G11C 11/4096

(52) U.S. Cl. CPC G11C 11/4096

(57) ABSTRACT

A test interface mode over general purpose input/output peripheral connectors of a multichip package (MCP) or system in package (SIP) for an integrated device chip having a wide functional interface. The wide functional interface has more signals than there are available external connectors on the SIP package. Logic in the SIP package includes selection logic to select one or more portions of the wide functional interface to test in a given cycle. Logic in the SIP package multiplexes peripheral connectors as a test interface for the device chip, instead of dedicating connectors on the SIP package for a direct access test interface.

### FIELD

Embodiments of the invention are generally related to multichip packages (MCPs), and more particularly to testing a wide functional interface of a chip in an MCP without the use of dedicated test pins on the MCP.

### COPYRIGHT NOTICE/PERMISSION

Portions of the disclosure of this patent document may contain material that is subject to copyright protection. The copyright owner has no objection to the reproduction by anyone of the patent document or the patent disclosure as it appears in the Patent and Trademark Office patent file or records, but otherwise reserves all copyright rights whatsoever. The copyright notice applies to all data as described below, and in the accompanying drawings hereto, as well as to any software described below: Copyright© 2013, Intel Corporation, All Rights Reserved.

### BACKGROUND

Multichip packaging is an advance that allows the integration of different computer system subsystems onto a common system substrate. Multichip packaging refers to the process, and a multichip package refers to the device resulting from the process; both can be represented by the acronym “MCP.” Such a system package can also be referred to as a system in package (SIP). An MCP or SIP can include a system on a chip (SOC), which can refer to a single chip with integrated system functionality. MCP allows for smaller form factors, improved energy efficiency, and increased bandwidth efficiency.

However, MCPs can include chips or device die from multiple different manufacturers. As the chips are integrated onto the same SIP, testing can be required for each individual device chip as well as the system as a whole. Thus, industry faces the need to test a “buried” interface, or an interface to a chip that is not directly accessible from the outside of the SIP package. The testing becomes increasingly challenging for device chips with wide functional interfaces, which have more signals than there are available connectors on the SIP package. Some wide interfaces for just one of the device chips in the SIP may have many times the number of total signals as there are connectors on the SIP package.

For example, certain integrated systems include a processor and a wide input/output (WIO) memory device (Wide IO2, specification in development as of the filing of this application), such as a WIO2 DRAM (dynamic random access memory). WIO2 DRAMs can include hundreds of signals in the functional interface. To test the DRAMs, manufacturers include a defined set of 40 direct access (DA) test pins, which allows direct access to the functional portions of the memory device without using the functional interface. Manufacturers typically expect that the DA test pins are routed to the package pins of the SIP in which they are integrated to allow for direct access testing of the DRAM. The design of the test interface does not allow other functions on the test pins. Allocating 40 connectors on a small SIP product package for testing one internal device of the SIP is a very large cost. However, not providing the DA pins creates a serious capability gap for testing of the DRAM in the SIP manufacturing flow, and for debug and failure analysis.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of an embodiment of a system in package (SIP) with a processor chip and a device chip with a wide functional interface integrated on the SIP.

FIG. 2 is a block diagram of an embodiment of an SIP having peripheral connectors selectively routed to a wide interface of an embedded integrated circuit chip, where the peripheral connectors are used as a test interface.

FIG. 3 is a block diagram of an embodiment of a memory device chip having a wide functional interface and a dedicated test interface, where logic on an SIP interfaces to external connectors to the wide functional interface instead of the test interface.

FIG. 4 is a block diagram of an embodiment of a test mode layout for a Wide Input/Output memory device.

FIG. 5 is a block diagram of an embodiment of interface logic for a device embedded on an SIP that supports a test mode to multiplex test traffic over general purpose external connectors.

FIG. 6 is a flow diagram of an embodiment of a process for providing test traffic to a device chip embedded in an SIP with a test mode for general purpose peripheral connectors.

FIG. 7 is a block diagram of an embodiment of a computing system in which a general purpose connector test mode can be implemented.

FIG. 8 is a block diagram of an embodiment of a mobile device in which a general purpose connector test mode can be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

As described herein, a test interface mode allows access to a device chip that is integrated into an SIP (system in package) or other MCP (multichip package). It will be understood that an SIP typically has a processor or other control logic device that controls the system, whereas an MCP does not necessarily have a processor or controlling device. When a device chip is integrated in an SIP or MCP, the interface of the device chip can be “buried” inside the package, meaning the interface is not directly accessible via connectors or pins on the SIP or MCP package. For purposes of simplicity, the disclosure will generally refer to an SIP and SIP package. It will be understood that except as specified, what is described applies equally well to MCP as to SIP. It will also be understood that an MCP or SIP can include a system on a chip (SOC), referring to a single chip with integrated system functionality, and/or can include another logic die. An MCP or SIP includes multiple device chips, at least one of which can be an SOC or other logic die that can cause an I/O interface to be not directly accessible via package connectors.

For such an integrated device chip, typically the SIP package provides indirect access to the functional interface of the integrated device chip through multiplexing of connectors on the SIP package to the various signals of the functional interface. Such indirect access is particularly true when the integrated device chip has a wide interface. A device with a wide interface can have a number of signals many times more than a total number of connectors available on the SIP package. A device with a wide interface can also be referred to as a device with a wide bandwidth bus or wide channel device. For such a device, the number of signals is impractically large to provide direct access to each signal as a separate pin or connector on the SIP package. In many cases, bringing the internal or buried interface out to the SIP package can have a detrimental impact on the performance of the SIP. In some cases, bringing the buried interface out to the SIP package could increase power usage due to extra loading. It will also be understood that bringing out the buried interface can increase the security risk of observing the signal. The SIP package includes pins, balls, or other external connectors on the package which allow connecting the SIP product to other devices or peripherals. For purposes of simplicity in description, reference to connectors or external connectors refers generally to any mechanism provided on the SIP package to connect to other devices. Signals of the device chip can refer to separate I/O points or connections points on the die that can be driven to trigger functionality of the device and/or read from to access data from the device.

Testing integrated device chips with buried interfaces has traditionally been performed by use of a test interface, with connectors for the test interface on the SIP package. Thus, an SIP manufacturer takes a known good die or device chip and integrates it into an SIP product. The SIP manufacturer can then test the die in-system to ensure that it still works as expected. One area that commonly uses such techniques is the area of memory devices. DRAM vendors provide tests for SIP manufacturers to perform, which rely on access to a dedicated test interface on the SIP package. The number of test connectors is significant (e.g., approximately 40 connectors or approximately 60 connectors), and are not used for any other purpose other than to test. Additionally, the test connectors test the functionality of the device chip without using the actual I/O pathways of the integrated wide interface.

A test interface mode allows multiplexing direct access test connectors onto general purpose I/O (GPIO) connectors of the SIP. The GPIO connectors are external connectors that are used to access a peripheral device outside the SIP that connects to the SIP. The SIP includes logic to multiplex or route the external connectors to the integrated device chip for testing. In one embodiment, the logic can include selection logic to select one or more portions of the functional interface to test in a given cycle. In one embodiment, logic in the SIP package multiplexes the external peripheral connectors as a test interface for the device chip, instead of dedicating connectors on the SIP package for a direct access test interface.

In one embodiment, the integrated device chip is a memory device die, such as a DRAM, with a wide functional interface. Thus, the SIP package can be configured to provide an alternative test access port to the memory device, overloading the test interface on the SIP GPIO connectors, which are the normal function pins or connectors for the SIP product. The test mode can be referred to as a GPIO Mode or GPIO Bypass Mode, and is a test and debug test mode which provides control of the memory device through the SIP GPIO connectors. In one embodiment, the SIP includes a TAP which can be triggering to put the SIP into GPIO mode. Triggering GPIO mode in the SIP can configure several digital (GPIO) connectors on the SIP package to the test mode, and logic in the SIP routes certain connectors to the device chip to test. In one embodiment, triggering GPIO mode in the SIP causes logic in the SIP to route certain external connectors to designated Logic Memory Interface (LMI) functional connectors of an integrated WIO2 DRAM device.

In general, a memory device can be either a nonvolatile or volatile memory device. A nonvolatile memory device has a determinate state even if system power provided to the memory device is interrupted. Volatile memory is memory whose state (and therefore the data stored on it) is indeterminate if system power is interrupted to the device. Volatile memory devices typically require refreshing the data stored in the device to maintain state. DRAM devices are generally volatile memory devices. A single die or device chip can include multiple different memory devices, or separately-addressable memory portions.

In one embodiment, a memory device is the integrated device chip with the buried interface. In one embodiment, the memory device has a wide functional interface. In one embodiment, the SIP can include chip select logic or a chip select mechanism that allows channel selectivity for selecting one or more channels to access on the memory device. Thus, for example, the test mode or GPIO mode for testing the memory device can test all channels simultaneously to determine worst case performance and/or test groups of channels as well as individual channels. Such selectivity allows properly testing marginalities in the memory device, as well as drilling down in a debug process to determine where issues may exist with the memory device. In one embodiment, circuit design of the logic and routing in the SIP focuses on meeting key clock skew requirements. In such an embodiment, the logic in the SIP can include chip select logic to allow for enabling all or a subset of channels to operate on each individual command to the memory device channels. The logical test interface can use only combinational logic paths instead of using clocked paths, which allows the testing to characterize and margin the IOs to the memory device.

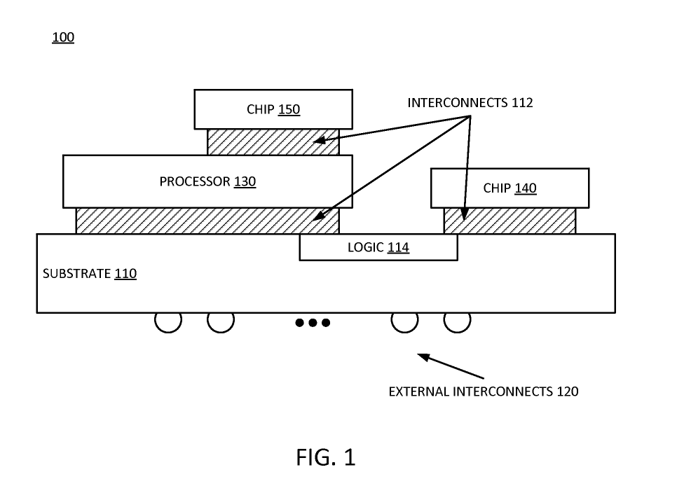

FIG. 1 is a block diagram of an embodiment of a system in package (SIP) with a processor chip and a device chip with a wide functional interface integrated on the SIP. System 100 represents a system on a chip or other multichip package. System 100 includes substrate 110, which represents a substrate on which the various different device chips of system 100 are integrated. Substrate 110 provides interconnection of the integrated chips to external interconnects or external connectors 120. Interconnects 120 represent the external connectors or connectors of the SIP package. As mentioned above, interconnects 120 can be implemented as pins, balls of a BGA (ball grid array), or other connection mechanism.

In an implementation of an SIP, system 100 includes processor 130. In an implementation of an MCP, system 100 does not necessarily include processor 130. Processor 130 is integrated onto substrate 110. Processor 130 provides control logic and control of system 100. In an MCP, processor 130 could be replaced with control logic that provides any necessary processing of signals, commands, and/or data for system 100. In one embodiment, logic 114 provides selection and routing logic within system 100. Logic 114 can be integrated or processed right into substrate 110 and interface the device chips of system 100 with external interconnects 120.

System 100 includes multiple device chips coupled to substrate 110. The device chips can all be of the same type, or can be of different types, such as a system configuration. Each chip is coupled with interconnects 112. Interconnects 112 are internal interconnects, and can include pins, balls, bonding wires, and/or other interconnection mechanisms. In one embodiment, multiple devices can be integrated into system 100 in a stacked configured, such as what is illustrated with respect to chip 150 being stacked on processor chip 130. Thus, chip 150 represents a device chip that is integrated into system 100 in a stacked configuration, which chip 140 represents a device chip that is integrated into system 100 directly onto substrate 110.

In one embodiment, system 100 includes processor 130 and a memory device chip with a wide functional interface. Chip 140 can represent a memory device integrated onto substrate 110, with interconnections to processor 130 provided via logic 114. WIO2 DRAM devices are wide interface devices that are designed to be stacked on another device chip, and receive all signals, including power, through the other device chip. Thus, chip 140 only indirectly interfaces substrate 110 via processor 130. Chip 150 can represent a memory device stacked on processor 130, with interconnects 112 directly providing all interconnections between the processor die and the memory die. HBM (high-bandwidth memory) devices are wide interface devices designed to be placed side by side with other devices in an SIP.

Logic 114 enables system 100 to provide test interface access to chip 140 and/or chip 150 via external interconnects 120. Unlike previous systems, external interconnects 120 does not need to include any dedicated test connectors. Rather, functional I/O connectors used to connect with devices external to system 100 are used in a test mode to access an interface of the device chip to be tested. External connectors 120 can include power and control connectors in addition to I/O connectors. Logic 114 multiplexes functional I/O connectors in the test mode as a test interface for chip 140, 150, instead of dedicating connectors on the SIP package solely for a direct access test interface. It will be understood that external connectors 120 used as a test interface in the test mode are not connectors dedicated to or associated with the chip having the buried interface to be test, except for purposes of testing. Thus, the testing signals can be overloaded onto non-dedicated I/O connectors.

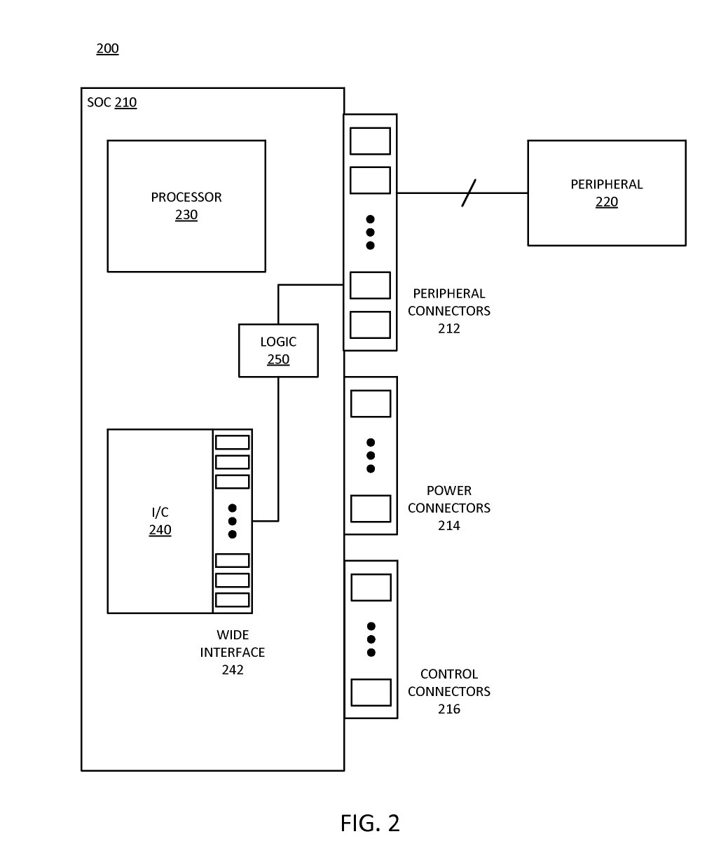

FIG. 2 is a block diagram of an embodiment of an SIP having peripheral connectors selectively routed to a wide interface of an embedded integrated circuit chip, where the peripheral connectors are used as a test interface. System 200 includes SIP 210 and peripheral 220. Peripheral 220 represents any device external to SIP 210 to which the SIP can be connected. The connection can be part of a larger system, and/or can be a connection to a standalone device that can provide functionality to and/or receive functionality from SIP 210. SIP 210 can be one example of an SIP in accordance with system 100 of FIG. 1. Peripheral 220 can connect to SIP 210 via a single connector, or more commonly via a connection bus.

SIP 210 includes processor 230, which provides the primary functional processing and functional control of SIP 210. I/C (integrated circuit) 240 represents an additional device chip integrated into SIP 210, such as a memory device. I/C 240 includes wide interface 242, which has more functional signals than there are functional connectors on SIP 210. The functional connectors on SIP 210 are labeled as peripheral connectors 212, indicating that they can generally be used to interface with peripheral devices. They are functional connectors in that they interface functional aspects of SIP 210 to other devices, as opposed to power connectors 214 and control connectors 216. Power connectors 214 provide power and ground sources to SIP 210. Control connectors 216 can include connectors dedicated to clock signal(s), alert and/or interrupt signals, and/or other dedicated signals. Peripheral connectors 212 include I/O interfaces that can exchange data and are operational exchanges, and are not necessarily tied to specific control or management functions of SIP 210.

Logic 250 routes peripheral connectors 212 to signals of wide interface 242. It will be understood that wide interface 242 can also include connections to power connectors 214 and/or control connectors 216, whether direct connections or indirect connections. Logic 250 provides a logic test interface for I/C 240, by routing peripheral connectors 212 to wide interface 242 to test the functionality of I/C 240 in a test mode of SIP 210. The test mode can be referred to as a GPIO mode, as referred to above.

The test mode as described herein requires no dedicated connectors on SIP 210 for testing the interface of I/C 240, in contrast to traditional DA (direct access) test methods. Additionally, it will be understood that testing the functions of I/C 240 by passing signals through wide interface 242 tests the native interface of the device in-system. DA testing methods bypass the functional interface of the device chip, instead using the direct access testing connections. Thus, DA connectors provide no or poor coverage of the native I/Os. In one embodiment, logic 250 includes selection logic to enable simultaneous operations on any one or more separate channels of I/C 240. Thus, for example, a memory device having eight memory channels can test all eight, or any subset of any of the eight memory channels tested simultaneously. Such testing allows worst case testing of power supply voltage droop, heat generation, and actual I/O activity.

In one embodiment, logic 250 multiplexes selected connectors of peripheral connectors 212 to wide interface 242 as illustrated. Thus, the testing can test the actual I/O paths of I/C 240. In an alternative embodiment, logic 250 can multiplex selected connectors of peripheral connectors 212 to a direct access test interface (not specifically shown in system 200). The advantage of multiplexing the peripheral connectors to the test interface means that SIP 210 does not need dedicated test-only connectors. However, routing peripheral connectors 212 to a test interface does not test the native I/O interface of I/C 240.

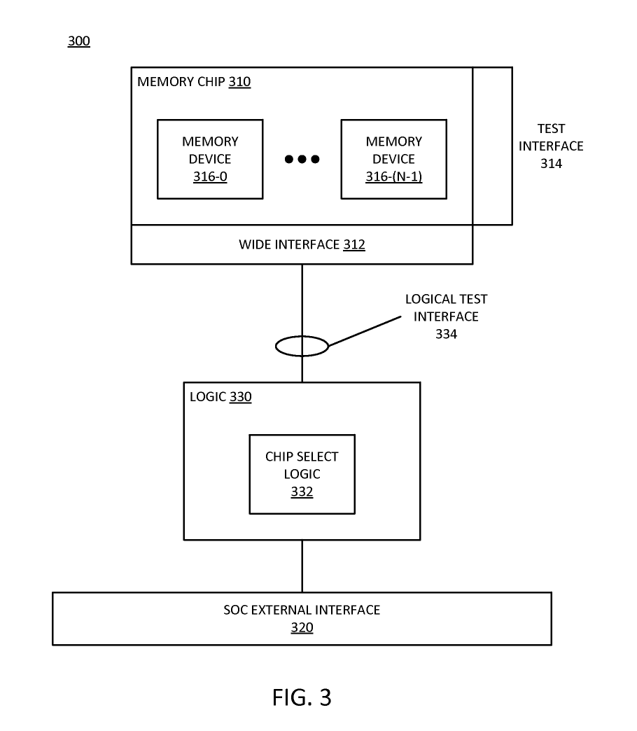

FIG. 3 is a block diagram of an embodiment of a memory device chip having a wide functional interface and a dedicated test interface, where logic on an SIP interfaces to external connectors to the wide functional interface instead of the test interface. System 300 represents elements of an SIP or MCP in accordance with any embodiment described herein, such as system 100 of FIG. 1, or SIP 210 of FIG. 2. More particularly, system 300 includes memory chip 310 as an I/C chip integrated in the SIP, which is routed to SIP external interface 320 via logic 330.

Memory chip 310 is a memory device chip that has wide interface 312, which represents a functional interface of the memory device chip. Memory chip 310 also includes test interface 314, which represents an interface having many fewer connections (which could be an order of magnitude fewer) than wide interface 312. Test interface 314 is exclusively for testing memory chip 310, and is not a functional interface. A functional interface receives and/or provides signals for active operation of the device. Test interface 314 only tests functionality, and does not provide or receive signal for active operation of memory chip 310.

In one embodiment, memory chip 310 includes separate memory device portions, represented by memory device 316-0 through memory device 316-(N−1). While labeled as “memory devices,” memory devices 316-0 through 316-(N−1) represents any segmenting of memory resources on memory chip 316, which may be as separate channels, separate DRAMs, or other allocation of the resources. In one embodiment, WIO2 DRAMs can be integrated as stacks of 2 or 4 DRAM chips that share the wide interface. Where WIO2 DRAMs are stacked, the DRAMs typically share a common DA connector group. Test interface 314 is traditionally only capable of interfacing with a single device 316 or channel at a time. Logic 330 includes chip select logic 332, which allows logic 330 to select any one or more device portion 316, up to all device portions. Thus, testing via logic 330 allows testing operation on any one, multiple, or all portions of memory chip 310 simultaneously (e.g., simultaneous operation on all memory channels).

SIP external interface 320 represents the external connectors on an SIP package in which memory chip 310 is integrated. Interface 320 includes at least a portion of peripheral or general purposes I/O connectors. In one embodiment, interface 320 does not include any dedicated test connectors. Logic 330 generally multiplexes connectors of interface 320 as a test interface for memory chip 310. Thus, logic 330 provides logical test interface 334 for memory chip 310, which can bypass test interface 314 and test memory chip 310 via its operational I/O paths.

In one embodiment, memory chip 310 includes 64 memory device portions 316 (i.e., where N=64), in which case all 64 portions of memory chip 310 can produce data for a read operation, and the output byte is determined by selection logic. Logic 330 can select which byte to read for the test via chip select logic 332. Logic 330 can generate a per-cycle selection to select a read byte. Thus, bytes from all portions can be read, but are read out one at a time. In one embodiment, for testing, logic 330 via chip select logic 332 can select one specific channel or memory device portion 316 to present a byte of write data.

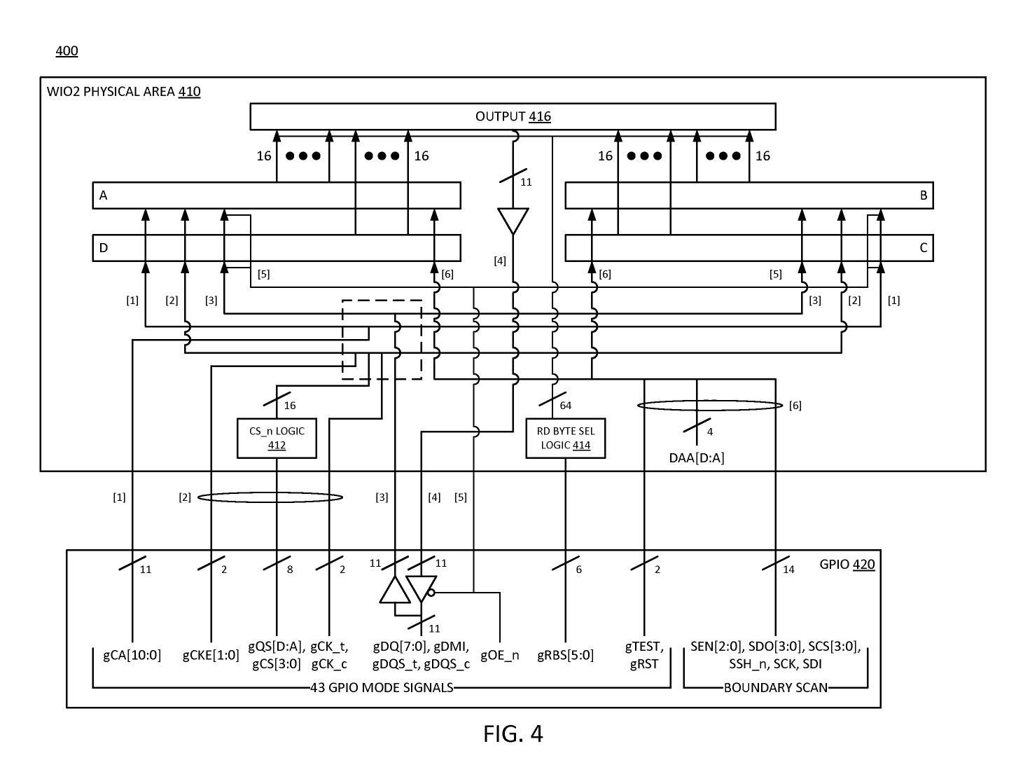

FIG. 4 is a block diagram of an embodiment of a test mode layout for a Wide Input/Output memory device. System 400 represents a more detailed view of certain aspects of a memory device as an I/C chip in a logic die (e.g., an SOC), selected external connectors, and a selected logic that enables routing the external connectors as a test interface for the memory device. More particularly, system 400 represents a logic device in which a WIO2 DRAM device could be integrated. The logic of system 400 could also apply to an SIP in which the DRAM device is integrated. Thus, the logic of system 400 could be applied to an SOC or SIP, and will generically be referred to as a “logic die,” referring to a die that can be integrated with others, or to logic integrated directed onto a chip. It will be understood that the example of system 400 is merely illustrative, and not limiting in any way. Other I/C device chips will have different designs and configurations, but the principles of selectively routing test signals as a test interface over functional interfaces will apply to other I/C device chips.

Area 410 represents a physical area of the WIO2 DRAM or memory device. A, B, C, and D represent four quadrants in the logic device. The four quadrants represent logic-memory interfaces (LMI) where a WIO2 DRAM would be connected. Thus, A, B, C, and D represent locations where one or more DRAM devices would be placed in the logic die. For a WIO2 DRAM, each quadrant includes two memory channels, for a total of eight memory channels. In one embodiment, area 410 includes approximately 1500 connections within the four quadrants, with roughly 800 signals. In each quadrant there are also 10 signal lines for direct access testing. In system 400, the testing interface is mapped onto GPIO connectors and DA signals are not brought out to the package connectors. Instead, the DA signals can be terminated on the logic die, and not mapped to GPIO connectors of the logic package. The GPIO connectors they are mapped to are normal functional channels, which turns the functional interface into the test interface by overloading the connectors and providing various chip select and/or other selectivity signals. The functional interface is the test interface for purposes of the GPIO mode or the test mode, and is otherwise the functional interface.

In one embodiment, WIO2 DRAM has 229 active signals at the LMI when in a GPIO mode or test mode for write cycles, and 781 active signals for read cycles (plus DAA and boundary scan signals). In one embodiment, as illustrated, the GPIO mode for system 400 includes 43 non-dedicated GPIO connectors on the logic die package (in addition to DAA and boundary scan signals), and maps to the 229 signals during write cycles, and 781 signals during read cycles. The 43 GPIO signals and the boundary scan signals are identified in the drawing, and do not all need to be identified in this description.

In one embodiment, the WIO2 DRAM enters the GPIO mode when the gTEST signal is asserted on the DRAM LMI. Thus, the DRAM enters GPIO mode and uses a subset of the LMI interface signals. It will be understood that each memory device supplier can implement GPIO mode differently internally to the DRAM, even for memory devices of the same type. Thus, system 400 illustrates a high-level overview of the signal routing of a logic die for the GPIO mode, and each actual physical implementation of the logic die GPIO routing can be different for WIO2 devices from different suppliers, and each memory device type can implement the GPIO mode differently. In one embodiment, which connectors of the I/C device are active in GPIO mode are defined by specification (e.g., by a standards-setting body).

In one embodiment, the GPIO mode implementation in a logic die reduces the LMI active signal count to 43 GPIO connectors, plus DAA and boundary scan signals. Certain DRAM GPIO mode signals (e.g., some of the slower signals) can be controlled via a TAP network, thus not requiring GPIO connectors. To reduce the number of signals on the logic package, the typical 16 functional CS connectors on the LMI interface can be reduced to eight with a combination of Quadrant Selects and Chip Selects. Additionally, two CKE connectors can be provided on the SIP package and replicated to all channels (e.g., eight channels), and support up to 2 ranks. Additionally, the Data connectors (e.g., DQs, DQSs, and DMIs) from the eight channels (64 bytes) on the LMI interface can be reduced to a single set of connectors at the logic package, with a single gRST_n signal provided on the logic package and replicated to the four RST[3:0]_n signals on the LMI interface.

Typically, all signals are buffered between the logic package and the LMI interface. In one embodiment, these paths are non-clocked, combinational logic only. The logic routes the collection of 43 SIP GPIO mode signals to near the WIO2 physical interface region, where the Chip Select logic and CKE logic are located (not specifically shown). In one embodiment, the WIO2 DRAM supports 16 chip select signals. To reduce the connector count on the SIP package, a set of four Channel Select and four Quadrant Select signals can be defined on the SIP GPIO mode connectors and OR-combined to produce most combinations of chip selects to the WIO2 DRAM. Such selection logic allows DRAM transactions (activate, read, write, precharge, refresh, or others) to be applied to all or subsets of the eight channels on the WIO2 DRAM.

With specific reference to the drawing, it will be seen that various signals are grouped and identified by the labels [1], [2], . . . , [6]. These labels do not have any meaning except to make it easier to trace the routing of the signals in the detailed drawing. Thus, for example, group [1] includes gCA[10:0], which is routed to each of the four quadrants (A, B, C, and D). Group [2] includes gCKE[1:0], the output of CS_n logic 412, gCK_t, and gCK_c, which is also routed to each of the four quadrants. gRBS[5:0] controls the output of read byte select logic 414, which acts to select one of the 64 outputs generated by the four quadrants, and shown as output 416. It will be understood that a read or a write “byte” is illustrated as including 11 signal lines. Thus, a byte refers to the eight DQ signals (DQ[7:0]), the associated two DQS signals (DQS_t, DQS_c), and the associated DMI signal, for a total of 11 signals. Different implementations can have different size bytes.

As mentioned above, system 400 or other such systems can be configured to simultaneously execute operations on all channels. Thus, a memory transaction presented on the SIP GPIO connectors can be executed on all WIO2 DRAM channels simultaneously, thus creating the worst case power delivery noise to the DRAM. It will be understood that simultaneous operation requires a mechanism to ensure that the timing skew between DRAM input signals (e.g., CK, CA, Data, DQS, others) is matched as presented at each of the DRAM channels, at least within timing specifications. Thus, in one embodiment, system 400 is designed to roughly match the routing flight time for the set of signals sent to each channel from a “T” point, as indicated by the dashed square around the common routing area or consolidation area. The consolidation area allows for matched timing between the two sides and among the different quadrants.

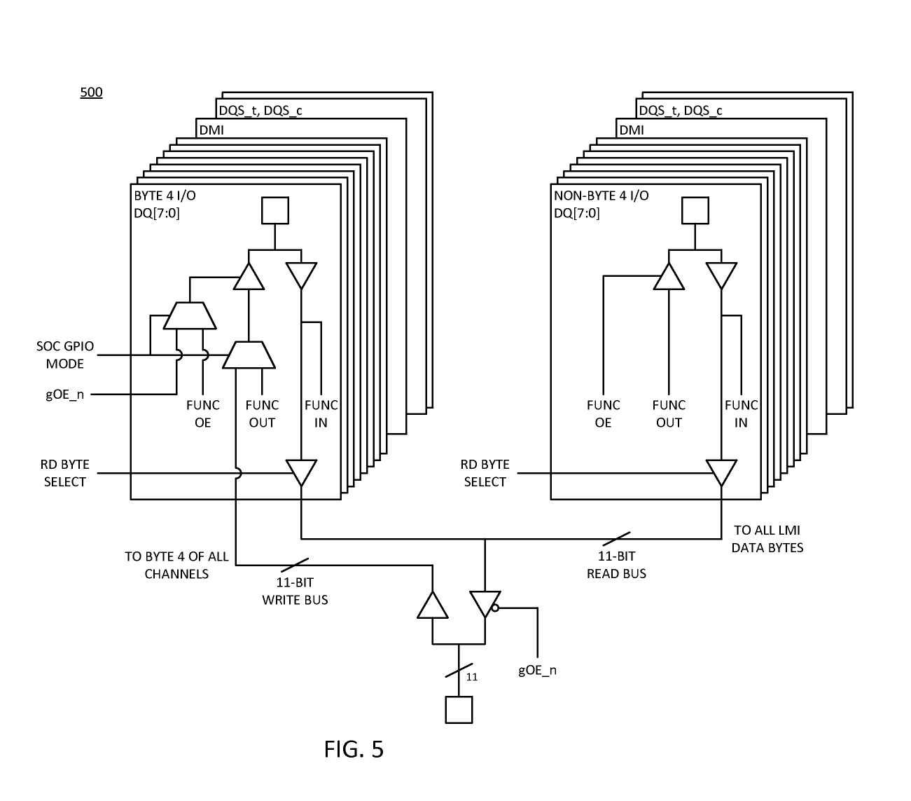

FIG. 5 is a block diagram of an embodiment of interface logic for an SIP or logic die that integrates a device that supports a test mode to multiplex test traffic over general purpose external connectors. System 500 illustrates logic of data I/O paths for the test interface of one embodiment of system 400 of FIG. 4. In one embodiment, system 500 executes write cycles to selected channels through just one byte per channel. In the WIO2 DRAM, Byte 4 can be used for GPIO mode. The DRAM supplier is responsible for how the DRAM receives and distributes byte 4 to the seven other bytes on the channel, and thus each implementation may be different.

It will be understood that timing between a data signal and a data strobe signal needs to be matched sufficiently to enable correct receiving of transmitted data. For example, the WIO2 specification specifies relatively tight timing requirements for aligning a DRAM clock signal to the write data strobes for the data connectors. The timing can be reasonably controlled for a single signal, but synchronizing multiple strobe signals with the clock can prove to be difficult. Thus, in one embodiment, data written to a DRAM in GPIO mode is only provided on Byte 4 of a channel. Therefore, test mode signals can be provided on Byte 4 which control the SOC LMI Byte 4 transmit buffer enable and the GPIO mode write data. Other bytes within the channel do not need to have GPIO test ode write data capability. Thus, as shown, there can be provided additional selection logic for Byte 4 relative to non-byte 4 I/O for write transactions for GPIO mode. The additional logic includes selection of the GPIO mode, which enables selection between the function enable and the GPIO enable, as well as the selection of function out or the GPIO write.

On read transactions, the DRAM operates normally, where valid read data comes out of all eight bytes on the selected channel, and logic on the logic die generates a select for the GPIO mode to provide a Read Byte Select signal. The Read Byte select signal determines which of the eight bytes from the eight channels is output to the logic package GPIO data connectors. The 64 byte to 1 byte reduction logic can be implemented as a mux tree select function (not shown), or as a multi-drop bus (similar to what is shown). In system 500, the logic enables the drivers of the read bus by decode logic. Note that a “byte” refers to the eight DQ signals (DQ[7:0]), the associated two DQS signals (DQS_t, DQS_c), and the associated DMI signal, for a total of 11 signals.

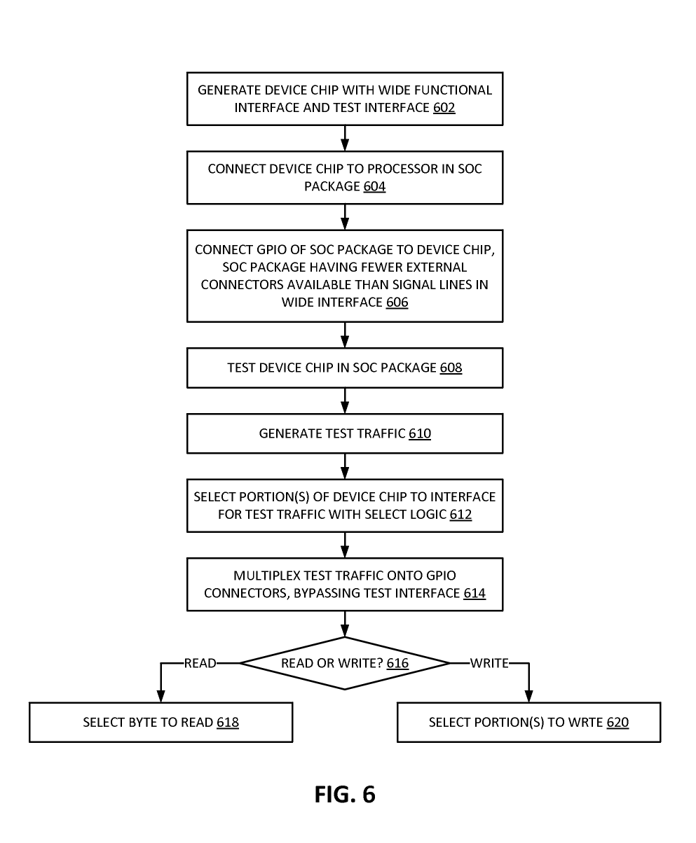

FIG. 6 is a flow diagram of an embodiment of a process for providing test traffic to a device chip embedded in an SIP with a test mode for general purpose peripheral connectors. An integrated circuit device chip manufacturer generates a device chip that has a functional interface. In one embodiment, the I/C chip has a wide functional interface and a test interface, 602. The functional interface enables exchange of commands and data between the I/C chip and one or more other chips. Typically, the chip is tested to determine if it meets expected performance parameters. Chips that meet expected performance parameters are considered “known good” and will be provided to other product manufacturers.

In one embodiment, a product manufacturer takes a known good I/C device chip and connects it in an MCP or SIP with a processor chip, 604. In one embodiment, the product manufacturer connects the I/C device chip to the processor chip. The SIP includes GPIO connectors on the package to provide functional access to the SIP, which in turn is provided by the functional operation of the chips in the SIP. Various GPIO connectors can be connected to the I/C device chip, 606. When the I/C device has a wide interface, the SIP package has fewer GPIO connectors on the SIP package than there are signals in the I/C device chip. As described herein, there are not GPIO connectors on the SIP package dedicated to the test interface of the I/C device chip.

In one embodiment, the product manufacturer tests the I/C device chip in-system in the SIP package, 608. The testing is performed via non-dedicated GPIO connectors on the SIP package. A test system generates test traffic, 610, and triggers the SIP for test mode. In the test mode, SIP selection and routing logic triggers an I/O path to the portion(s) of the I/C device chip to test. The SIP logic includes select logic that selects one or more portions of the device chip to interface with the test traffic, 612. In one embodiment, the portions are separate channels and/or selected bytes of data.

In one embodiment, the logic multiplexes the test traffic signals between the GPIO connectors to the device chip, bypassing the test interface of the device chip, 614. Thus, the testing can be provided over the native I/O path of the device chip. In one embodiment, the logic multiplexes the test traffic signals between the GPIO connectors to the test interface. The select logic can make a different selection and provide different routing on a per-cycle basis. Thus, for each cycle, the logic can determine if the test operation is a read or write, 616. For a read, the logic selects a byte to read, 618. In one embodiment, on read cycles the I/C device chip can generate output bytes on all channels, and the logic can select a specific byte to read out. For a write, the logic selects one or more portions of the device chip to write, 620. On write cycles, the system can use the logic as a chip select mechanism to present write data to a single channel. In one embodiment, the channel will see the presented data as write data, depending on its chip select (e.g., whether or not it is in test mode).

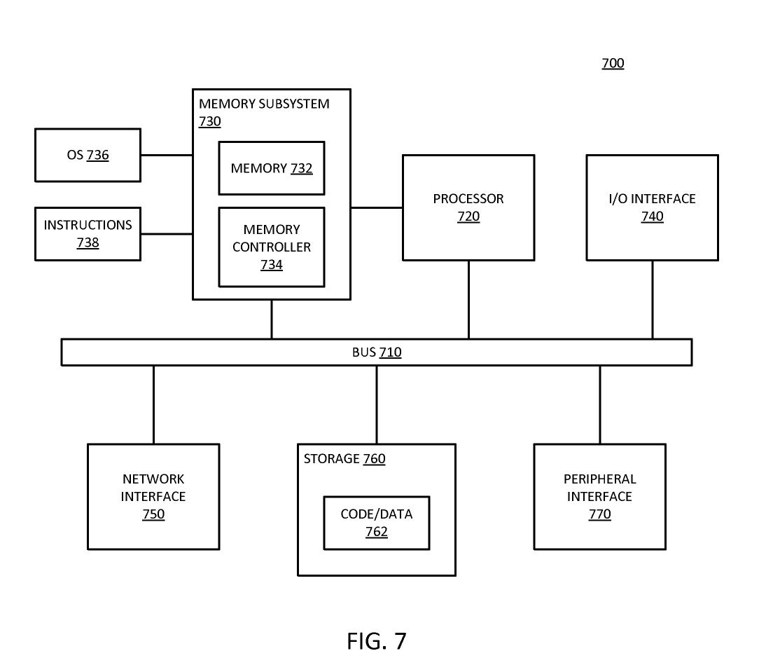

FIG. 7 is a block diagram of an embodiment of a computing system in which a general purpose connector test mode can be implemented. System 700 represents a computing device in accordance with any embodiment described herein, and can be a laptop computer, a desktop computer, a server, a gaming or entertainment control system, a scanner, copier, printer, routing or switching device, or other electronic device. System 700 includes processor 720, which provides processing, operation management, and execution of instructions for system 700. Processor 720 can include any type of microprocessor, central processing unit (CPU), processing core, or other processing hardware to provide processing for system 700. Processor 720 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 730 represents the main memory of system 700, and provides temporary storage for code to be executed by processor 720, or data values to be used in executing a routine. Memory subsystem 730 can include one or more memory devices such as read-only memory (ROM), flash memory, one or more varieties of random access memory (RAM), or other memory devices, or a combination of such devices. Memory subsystem 730 stores and hosts, among other things, operating system (OS) 736 to provide a software platform for execution of instructions in system 700. Additionally, other instructions 738 are stored and executed from memory subsystem 730 to provide the logic and the processing of system 700. OS 736 and instructions 738 are executed by processor 720. Memory subsystem 730 includes one or more memory devices 732 where it stores data, instructions, programs, or other items. In one embodiment, memory subsystem includes memory controller 734, which is a memory controller to generate and issue commands to memory device 732. It will be understood that memory controller 734 could be a physical part of processor 720.

Processor 720 and memory subsystem 730 are coupled to bus/bus system 710. Bus 710 is an abstraction that represents any one or more separate physical buses, communication lines/interfaces, and/or point-to-point connections, connected by appropriate bridges, adapters, and/or controllers. Therefore, bus 710 can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 710 can also correspond to interfaces in network interface 750.

System 700 also includes one or more input/output (I/O) interface(s) 740, network interface 750, one or more internal mass storage device(s) 760, and peripheral interface 770 coupled to bus 710. I/O interface 740 can include one or more interface components through which a user interacts with system 700 (e.g., video, audio, and/or alphanumeric interfacing). Network interface 750 provides system 700 the ability to communicate with remote devices (e.g., servers, other computing devices) over one or more networks. Network interface 750 can include an Ethernet adapter, wireless interconnection components, USB (universal serial bus), or other wired or wireless standards-based or proprietary interfaces.

Storage 760 can be or include any conventional medium for storing large amounts of data in a nonvolatile manner, such as one or more magnetic, solid state, or optical based disks, or a combination. Storage 760 holds code or instructions and data 762 in a persistent state (i.e., the value is retained despite interruption of power to system 700). Storage 760 can be generically considered to be a “memory,” although memory 730 is the executing or operating memory to provide instructions to processor 720. Whereas storage 760 is nonvolatile, memory 730 can include volatile memory (i.e., the value or state of the data is indeterminate if power is interrupted to system 700).

Peripheral interface 770 can include any hardware interface not specifically mentioned above. Peripherals refer generally to devices that connect dependently to system 700. A dependent connection is one where system 700 provides the software and/or hardware platform on which operation executes, and with which a user interacts.

In one embodiment, one or more elements of system 700 are implemented as device chips integrated into an MCP and/or an SIP device. In one embodiment, one or more device chips include memory devices 732 having a wide interface, and are tested in an MCP or SIP package by using non-dedicated connectors as a test interface. The MCP or SIP includes logic to select one or more portions of an integrated device chip to test.

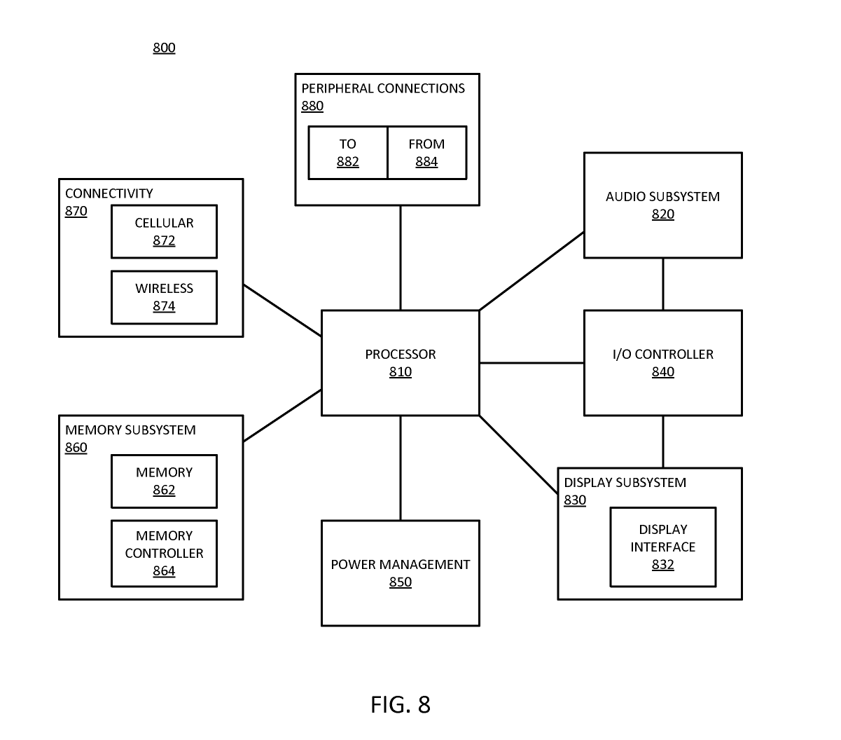

FIG. 8 is a block diagram of an embodiment of a mobile device in which a general purpose connector test mode can be implemented. Device 800 represents a mobile computing device, such as a computing tablet, a mobile phone or smartphone, a wireless-enabled e-reader, wearable computing device, or other mobile device. It will be understood that certain of the components are shown generally, and not all components of such a device are shown in device 800.

Device 800 includes processor 810, which performs the primary processing operations of device 800. Processor 810 can include one or more physical devices, such as microprocessors, application processors, microcontrollers, programmable logic devices, or other processing means. The processing operations performed by processor 810 include the execution of an operating platform or operating system on which applications and/or device functions are executed. The processing operations include operations related to I/O (input/output) with a human user or with other devices, operations related to power management, and/or operations related to connecting device 800 to another device. The processing operations can also include operations related to audio I/O and/or display I/O.

In one embodiment, device 800 includes audio subsystem 820, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 800, or connected to device 800. In one embodiment, a user interacts with device 800 by providing audio commands that are received and processed by processor 810.

Display subsystem 830 represents hardware (e.g., display devices) and software (e.g., drivers) components that provide a visual and/or tactile display for a user to interact with the computing device. Display subsystem 830 includes display interface 832, which includes the particular screen or hardware device used to provide a display to a user. In one embodiment, display interface 832 includes logic separate from processor 810 to perform at least some processing related to the display. In one embodiment, display subsystem 830 includes a touchscreen device that provides both output and input to a user.

I/O controller 840 represents hardware devices and software components related to interaction with a user. I/O controller 840 can operate to manage hardware that is part of audio subsystem 820 and/or display subsystem 830. Additionally, I/O controller 840 illustrates a connection point for additional devices that connect to device 800 through which a user might interact with the system. For example, devices that can be attached to device 800 might include microphone devices, speaker or stereo systems, video systems or other display device, keyboard or keypad devices, or other I/O devices for use with specific applications such as card readers or other devices.

As mentioned above, I/O controller 840 can interact with audio subsystem 820 and/or display subsystem 830. For example, input through a microphone or other audio device can provide input or commands for one or more applications or functions of device 800. Additionally, audio output can be provided instead of or in addition to display output. In another example, if display subsystem includes a touchscreen, the display device also acts as an input device, which can be at least partially managed by I/O controller 840. There can also be additional buttons or switches on device 800 to provide I/O functions managed by I/O controller 840.

In one embodiment, I/O controller 840 manages devices such as accelerometers, cameras, light sensors or other environmental sensors, gyroscopes, global positioning system (GPS), or other hardware that can be included in device 800. The input can be part of direct user interaction, as well as providing environmental input to the system to influence its operations (such as filtering for noise, adjusting displays for brightness detection, applying a flash for a camera, or other features). In one embodiment, device 800 includes power management 850 that manages battery power usage, charging of the battery, and features related to power saving operation.

Memory subsystem 860 includes memory device(s) 862 for storing information in device 800. Memory subsystem 860 can include nonvolatile (state does not change if power to the memory device is interrupted) and/or volatile (state is indeterminate if power to the memory device is interrupted) memory devices. Memory 860 can store application data, user data, music, photos, documents, or other data, as well as system data (whether long-term or temporary) related to the execution of the applications and functions of system 800. In one embodiment, memory subsystem 860 includes memory controller 864 (which could also be considered part of the control of system 800, and could potentially be considered part of processor 810). Memory controller 864 includes a scheduler to generate and issue commands to memory device 862.

Connectivity 870 includes hardware devices (e.g., wireless and/or wired connectors and communication hardware) and software components (e.g., drivers, protocol stacks) to enable device 800 to communicate with external devices. The external device could be separate devices, such as other computing devices, wireless access points or base stations, as well as peripherals such as headsets, printers, or other devices.

Connectivity 870 can include multiple different types of connectivity. To generalize, device 800 is illustrated with cellular connectivity 872 and wireless connectivity 874. Cellular connectivity 872 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 874 refers to wireless connectivity that is not cellular, and can include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 880 include hardware interfaces and connectors, as well as software components (e.g., drivers, protocol stacks) to make peripheral connections. It will be understood that device 800 could both be a peripheral device (“to” 882) to other computing devices, as well as have peripheral devices (“from” 884) connected to it. Device 800 commonly has a “docking” connector to connect to other computing devices for purposes such as managing (e.g., downloading and/or uploading, changing, synchronizing) content on device 800. Additionally, a docking connector can allow device 800 to connect to certain peripherals that allow device 800 to control content output, for example, to audiovisual or other systems.

In addition to a proprietary docking connector or other proprietary connection hardware, device 800 can make peripheral connections 880 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

In one embodiment, one or more elements of system 800 are implemented as device chips integrated into an MCP and/or an SIP device. In one embodiment, one or more device chips include memory devices 862 having a wide interface, and are tested in an MCP or SIP package by using non-dedicated connectors as a test interface. The MCP or SIP includes logic to select one or more portions of an integrated device chip to test.

In one aspect, a multichip package (MCP) device with a multiplexed test interface for an integrated chip, includes: a package having a substrate and multiple external connectors to connect to signals external to the MCP including power connectors for power signals and peripheral connectors to couple to an external peripheral device; an integrated circuit chip coupled to the substrate, the integrated circuit chip having a wide functional interface including more signals than a number of the external connectors on the package; and logic to multiplex peripheral connectors as a test interface for the additional chip, instead of dedicating connectors on the package solely for a direct access test interface.

In one embodiment, the MCP device further includes a processor chip integrated on the substrate and coupled to the integrated circuit chip. In one embodiment, the integrated circuit chip comprises a memory device chip. In one embodiment, the logic further comprises chip select logic that selectively triggers any one or more of a total number of memory channels available on the memory device chip for simultaneous operation. In one embodiment, wherein for a read operation, the memory device chip is to generate output bytes from all bytes in a channel, and wherein the logic further comprises select logic that selects, per cycle, one of the bytes to read out. In one embodiment, wherein for a write operation, the logic further comprises select logic that presents a byte of write data to a specific memory channel. In one embodiment, wherein the integrated circuit chip is stacked on another device chip coupled to the substrate, and interfaces the substrate indirectly via the other device chip. In one embodiment, wherein the integrated circuit chip comprises a wide interface memory device chip, and the other device chip comprises a processor chip. In one embodiment, wherein the logic is to multiplex selected ones of the peripheral connectors as the test interface to the wide functional interface, bypassing the direct access test interface.

In one aspect, an electronic device with a multiplexed test interface for an integrated chip, includes: a multichip package (MCP) device including an MCP package having a substrate and multiple external connectors to connect to signals external to the MCP including power connectors for power signals and peripheral connectors to couple to an external peripheral device; a processor chip integrated on the substrate; memory device chip coupled to the processor chip, the memory device chip having a wide functional interface including more signals than a number of the external connectors on the MCP package; and logic to multiplex peripheral connectors as a test interface for the memory device chip, instead of dedicating connectors on the MCP package solely for a direct access test interface; and a touchscreen display coupled to generate a display based on data accessed from the memory device chip.

In one embodiment, the logic further comprises chip select logic that selectively triggers any one or more of a total number of memory channels available on the memory device chip for simultaneous operation. In one embodiment, for a read operation, the memory device chip is to generate output bytes from all bytes in a channel, and wherein the logic further comprises select logic that selects, per cycle, one of the bytes to read out. In one embodiment, for a write operation, the logic further comprises select logic that presents a byte of write data to a specific memory channel. In one embodiment, the memory device chip is stacked on the processor chip, and interfaces the substrate indirectly via the processor chip. In one embodiment, the logic is to multiplex selected ones of the peripheral connectors as the test interface to the wide functional interface, bypassing the direct access test interface.

In one aspect, a method for multiplexing a test interface for an integrated chip, includes: selecting, for a device chip integrated into a multichip package (MCP), with logic that multiplexes peripheral connectors of a package of the MCP to the device chip, a portion of a wide interface of the device chip to test with test traffic, the additional chip having a wide functional interface including more functional signals than a number of the peripheral connectors on the MCP package; generating test traffic to test the wide interface; and multiplexing the test traffic over the peripheral connectors as a test interface for the device chip, instead of dedicating connectors on the MCP package solely for a direct access test interface.

In one embodiment, the device chip comprises a memory device chip. In one embodiment, the selecting further comprises selectively triggering any one or more of a total number of memory channels available on the memory device chip for simultaneous operation. In one embodiment, for a read operation the memory device chip is to generate output bytes from all bytes in a channel, and wherein the selecting comprises selecting, per cycle, one of the output bytes to read out. In one embodiment, for a write operation, the selecting comprises presenting a byte of write data to a specific memory channel. In one embodiment, the memory device chip is stacked on a processor chip, and interfaces the MCP package indirectly via the processor chip. In one embodiment, multiplexing comprises multiplexing selected ones of the peripheral connectors as the test interface to the wide functional interface, bypassing the direct access test interface.

In one aspect, an article of manufacture comprising a computer readable storage medium having content stored thereon, which when executed by a computing device performs operations for multiplexing a test interface for an integrated chip, includes: selecting, for a device chip integrated into a multichip package (MCP), with logic that multiplexes peripheral connectors of a package of the MCP to the device chip, a portion of a wide interface of the device chip to test with test traffic, the additional chip having a wide functional interface including more functional signals than a number of the peripheral connectors on the MCP package; generating test traffic to test the wide interface; and multiplexing the test traffic over the peripheral connectors as a test interface for the device chip, instead of dedicating connectors on the MCP package solely for a direct access test interface.

In one embodiment, the device chip comprises a memory device chip. In one embodiment, the content for selecting further comprises content for selectively triggering any one or more of a total number of memory channels available on the memory device chip for simultaneous operation. In one embodiment, for a read operation the memory device chip is to generate output bytes from all bytes in a channel, and wherein the content for selecting comprises content for selecting, per cycle, one of the output bytes to read out. In one embodiment, for a write operation, the content for selecting comprises content for presenting a byte of write data to a specific memory channel. In one embodiment, the memory device chip is stacked on a processor chip, and interfaces the MCP package indirectly via the processor chip. In one embodiment, the content for multiplexing comprises content for multiplexing selected ones of the peripheral connectors as the test interface to the wide functional interface, bypassing the direct access test interface.

In one embodiment, an apparatus for multiplexing a test interface for an integrated chip, includes: means for selecting, for a device chip integrated into a multichip package (MCP), with logic that multiplexes peripheral connectors of a package of the MCP to the device chip, a portion of a wide interface of the device chip to test with test traffic, the additional chip having a wide functional interface including more functional signals than a number of the peripheral connectors on the MCP package; means for generating test traffic to test the wide interface; and means for multiplexing the test traffic over the peripheral connectors as a test interface for the device chip, instead of dedicating connectors on the MCP package solely for a direct access test interface.

In one embodiment, the device chip comprises a memory device chip. In one embodiment, the means for selecting further comprises means for selectively triggering any one or more of a total number of memory channels available on the memory device chip for simultaneous operation. In one embodiment, for a read operation the memory device chip is to generate output bytes from all bytes in a channel, and wherein the means for selecting comprises means for selecting, per cycle, one of the output bytes to read out. In one embodiment, for a write operation, the means for selecting comprises means for presenting a byte of write data to a specific memory channel. In one embodiment, the memory device chip is stacked on a processor chip, and interfaces the MCP package indirectly via the processor chip. In one embodiment, the means for multiplexing comprises means for multiplexing selected ones of the peripheral connectors as the test interface to the wide functional interface, bypassing the direct access test interface.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A multichip package (MCP) device comprising:
a package having a substrate and multiple external connectors to connect to signals external to the MCP including power connectors for power signals and peripheral connectors to couple to an external peripheral device;
an integrated circuit chip coupled to the substrate, the integrated circuit chip having a wide functional interface including more signals than a number of the external connectors on the package; and
logic to multiplex peripheral connectors as a test interface for the additional chip, instead of dedicating connectors on the package solely for a direct access test interface.

2. The MCP device of claim 1 further comprising:
a processor chip integrated on the substrate and coupled to the integrated circuit chip.

3. The MCP device of claim 1, wherein the integrated circuit chip comprises a memory device chip.

4. The MCP device of claim 3, wherein the logic further comprises chip select logic that selectively triggers any one or more of a total number of memory channels available on the memory device chip for simultaneous operation.

5. The MCP device of claim 3, wherein for a read operation, the memory device chip is to generate output bytes from all bytes in a channel, and wherein the logic further comprises select logic that selects, per cycle, one of the bytes to read out.

6. The MCP device of claim 3, wherein for a write operation, the logic further comprises select logic that presents a byte of write data to a specific memory channel.

7. The MCP device of claim 1, wherein the integrated circuit chip is stacked on another device chip coupled to the substrate, and interfaces the substrate indirectly via the other device chip.

8. The MCP device of claim 1, wherein the integrated circuit chip comprises a wide interface memory device chip, and the other device chip comprises a processor chip.

9. The MCP device of claim 1, wherein the logic is to multiplex selected ones of the peripheral connectors as the test interface to the wide functional interface, bypassing the direct access test interface.

10. An electronic device comprising:
a multichip package (MCP) device including
an MCP package having a substrate and multiple external connectors to connect to signals external to the MCP including power connectors for power signals and peripheral connectors to couple to an external peripheral device;
a processor chip integrated on the substrate;
memory device chip coupled to the processor chip, the memory device chip having a wide functional interface including more signals than a number of the external connectors on the MCP package; and
logic to multiplex peripheral connectors as a test interface for the memory device chip, instead of dedicating connectors on the MCP package solely for a direct access test interface; and
a touchscreen display coupled to generate a display based on data accessed from the memory device chip.

11. The electronic device of claim 10, wherein the logic further comprises chip select logic that selectively triggers any one or more of a total number of memory channels available on the memory device chip for simultaneous operation.

12. The electronic device of claim 10, wherein for a read operation, the memory device chip is to generate output bytes from all bytes in a channel, and wherein the logic further comprises select logic that selects, per cycle, one of the bytes to read out.

13. The electronic device of claim 10, wherein for a write operation, the logic further comprises select logic that presents a byte of write data to a specific memory channel.

14. The electronic device of claim 10, wherein the memory device chip is stacked on the processor chip, and interfaces the substrate indirectly via the processor chip.

15. The electronic device of claim 10, wherein the logic is to multiplex selected ones of the peripheral connectors as the test interface to the wide functional interface, bypassing the direct access test interface.

16. A method comprising:
selecting, for a device chip integrated into a multichip package (MCP), with logic that multiplexes peripheral connectors of a package of the MCP to the device chip, a portion of a wide interface of the device chip to test with test traffic, the additional chip having a wide functional interface including more functional signals than a number of the peripheral connectors on the MCP package;
generating test traffic to test the wide interface; and
multiplexing the test traffic over the peripheral connectors as a test interface for the device chip, instead of dedicating connectors on the MCP package solely for a direct access test interface.

17. The method of claim 16, wherein the device chip comprises a memory device chip.

18. The method of claim 17, wherein the selecting further comprises selectively triggering any one or more of a total number of memory channels available on the memory device chip for simultaneous operation.

19. The method of claim 17, wherein for a read operation the memory device chip is to generate output bytes from all bytes in a channel, and wherein the selecting comprises selecting, per cycle, one of the output bytes to read out.

20. The method of claim 17, wherein for a write operation, the selecting comprises presenting a byte of write data to a specific memory channel.
